(19) United States
(12) Patent Application Publication
(10) Pub. No.: US 2026/0247962 A1
(43) Pub. Date: Aug. 20, 2026

(54) POWER MODULE AND METHOD FOR PRODUCING SAME, POWER CONVERTER COMPRISING A POWER MODULE

(71) Applicant: SCHAEFFLER TECHNOLOGIES AG & CO., KG, Herzogenaurach (DE)

(72) Inventors: Alexander Sauermann, Nürnberg (DE); Harald Vollath, Dittenheim (DE); Rohit Katkar, Nürnberg (DE)

(73) Assignee: SCHAEFFLER TECHNOLOGIES AG & CO., KG, Herzogenaurach (DE)

(21) Appl. No.: 18/995,281

(22) PCT Filed: Jul. 19, 2023
(86) PCT No.: PCT/EP2023/070035

§ 371 Date: Jan. 16, 2025

(30) Foreign Application Priority Data
Jul. 22, 2022 (DE) 10 2022 207 525.0

(51) Int. Cl. H10W 40/20; H02M 3/00; H02M 7/00; H05K 7/20; H10W 40/00; H10W 40/22; H10W 40/25; H10W 40/47; H10W 70/05; H10W 70/60; H10W 70/66; H10W 72/00; H10W 90/00; H10W 90/10

(52) U.S. Cl. CPC H10W 40/235; H10W 40/037; H10W 40/226; H10W 40/233; H10W 40/242; H10W 40/258; H10W 70/05; H10W 70/616; H10W 70/66; H02M 3/003; H02M 7/003; H05K 7/209; H05K 7/20927; H10W 40/47; H10W 72/075; H10W 90/10; H10W 90/754; H10W 90/764

(57) ABSTRACT

A power module which has a cooler, an insulation layer provided on a surface of the cooler, a conductor layer structure provided on the insulation layer and a plurality of heat- and current-conducting elements, each having an upper side and a lower side. The upper side is configured to form an electrical connection for an electronic component and the lower side is configured to make direct contact with the conductor layer structure. Also disclosed are a method for producing such a power module, and a power converter having such a power module.

### CROSS REFERENCE TO RELATED APPLICATIONS

This application is the U.S. National Phase Application of PCT International Application No. PCT/EP2023/070035, filed Jul. 19, 2023, which claims priority to German Patent Application No. 10 2022 207 525.0, filed Jul. 22, 2022, the contents of such applications being incorporated by reference herein.

### FIELD OF THE INVENTION

The present invention relates to the technical field of power electronics. The present invention relates in particular to a power module and a method for producing same. The present invention also relates to a power converter, in particular an inverter or a DC voltage converter, having a power module.

### BACKGROUND OF THE INVENTION

US 2017/154877 A1, incorporated herein by reference, describes a power module having a plurality of insulation layers between cooler and electronic components. This structure takes up a lot of space and can also be improved in terms of heat conduction and associated cooling efficiency.

### SUMMARY OF THE INVENTION

An aspect of the present invention is a compact power module with improved cooling efficiency.

According to a first aspect of the invention, a power module is described which has:
a cooler having a surface,
an electrically insulating (and thermally conductive) insulation layer formed on the surface of the cooler,
an electrically conductive conductor layer structure formed on a side of the insulation layer facing away from the cooler, and
a plurality of heat- and current-conducting elements made of a metal or a metal alloy or copper or a copper alloy, each having an upper side and a lower side, wherein the respective lower side of the respective heat- and current-conducting elements is arranged (directly) on the conductor layer structure and is electrically and thermally (conductively) connected (directly or only via electrically and thermally conductive materially bonded connections) to the conductor layer structure,
semiconductor components which are each arranged on the upper side of the respective heat- and current-conducting elements and are electrically and thermally (conductively) connected (directly or only via electrically and thermally conductive materially bonded connections) to the respective heat- and current-conducting elements.

The power module described is based on the knowledge that direct contact between the lower side of the heat- and current-conducting elements, which also serve as heat distributors, and a conductor layer structure provided directly on the cooler enables very efficient heat conduction and thus good cooling efficiency in a compact structure.

According to one exemplary embodiment of the invention, the insulation layer is formed of an electrically insulating material, in particular of an organic electrically insulating material or a ceramic electrically insulating material.

According to a further exemplary embodiment of the invention, the conductor layer structure is formed of an electrically and thermally conductive material or a metal or copper.

By way of example, the insulation layer and the conductor layer structure or the electrical contact areas formed therefrom and optionally also conductor paths are part of the cooler. Semiconductor components can be attached to this conductor layer structure directly or via a support fitted with the semiconductor components, in particular after the insulation layer and the conductor layer structure have been attached to the cooler. An optionally present support between the semiconductor components and the main body of the cooler is not part of the cooler; rather, such a support (or the semiconductor component itself) on the conductor layer structure of the cooler, which is supported by the insulation layer of the cooler, is an element which is arranged on the cooler. The cooler having conductor layer structure and insulation layer can be provided as a separate component for heat dissipation and be set up to carry the semiconductor components as mentioned.

According to a further exemplary embodiment of the invention, the underside of the heat- and current-conducting elements is soldered or sintered or glued or welded onto the conductor layer structure.

According to a further exemplary embodiment of the invention, the semiconductor components are each soldered or sintered or glued or welded onto the upper side of the respective heat- and current-conducting elements.

The insulation layer and the conductor layer structure can thus together provide a PCB-like surface structure of the cooler, on which the heat- and current-conducting elements can be directly mounted, e.g. soldered or sintered or glued or welded.

According to a further exemplary embodiment of the invention, the conductor layer structure has a plurality of areas which are physically and thus electrically separated from each other. In particular, the areas are rectangular, triangular, elliptical, circular or consist of one or more polygons.

Each area preferably has a shape and size which correspond to the shape and size of the lower side of at least one of the heat- and current-conducting elements or whose respective corresponding extents are only slightly larger.

According to a further exemplary embodiment of the invention, arranged on each of the areas in each case is at least one heat- and current-conducting element which is electrically and thermally (conductively) connected to the respective area.

According to a further exemplary embodiment of the invention, the areas are arranged in groups of three. In this case, the three areas of the respective group of three form (or provide) a negative current connection, a phase current connection and a positive current connection, respectively, of the power module or of a switching bridge.

Each group of three areas forms, for example, three electrical contact areas of a switching bridge for making contact with the heat- and current-conducting elements.

According to a further exemplary embodiment of the invention, the heat- and current-conducting elements are plate- or block-shaped. In particular, the heat- and current-conducting elements are punched out or cut out from a copper sheet.

The choice between relatively thin plate-shaped heat- and current-conducting elements or relatively thicker block-shaped heat- and current-conducting elements depends on the circumstances, in particular the required heat conduction and distribution.

According to a further exemplary embodiment of the invention, the heat- and current-conducting elements are arranged in groups of three. In this case, the three heat- and current-conducting elements of the respective group of three form (or provide) a negative current connection, a phase current connection and a positive current connection, respectively, of the power module.

According to a further exemplary embodiment, the power module further has electrically (and also thermally) conductive spacers which are each soldered or sintered or glued or welded onto the upper side of the respective heat- and current-conducting elements. The spacers are set up to make electrical connections between the heat- and current-conducting elements on the one side and external electrical contact partners, such as, e.g., bus bars, of the power module on the other side and at the same time to establish or to ensure spatial distance between the heat- and current-conducting elements on the one side and the external electrical contact partners on the other side. In this case, the spacers are, for example, block-shaped or column-shaped.

According to a further exemplary embodiment of the invention, the cooler has a heat sink and/or a liquid cooler, in particular an active liquid cooler.

According to a second aspect of the invention, a method for producing an above-described power module is described.

According to the method, a cooler is provided (step (a)). An electrical insulation layer is formed on a surface of the cooler (step (b)). An electrically conductive conductor layer structure is formed on a side of the insulation layer facing away from the cooler (step (c)). A plurality of heat- and current-conducting elements (108A, 108B, 108C), each having an upper side and a lower side, are provided (step (d)). The heat- and current-conducting elements are arranged on a side of the conductor layer structure facing away from the cooler. In this case, the respective lower side of the heat- and current-conducting elements is placed onto the conductor layer structure and is electrically and thermally connected to the conductor layer structure (step (e)). Semiconductor components are then provided and arranged on the respective heat- and current-conducting elements. In this case, the semiconductor components are each arranged on the respective corresponding heat- and current-conducting elements and electrically and thermally connected to the respective heat- and current-conducting elements (step (f)).

The described method is based substantially on the same idea as the above power module according to the first aspect and in particular provides a method for producing such a power module. In particular, steps (b) and (c) can be carried out in various ways in this case. For example, a material consisting of insulating material and conductor material can be applied to the surface of the cooler and the conductor layer structure can be provided by selective removal of conductor material. Alternatively, the insulation layer can be applied to the surface of the cooler first and the conductor layer structure can then be created by applying conductor material to the insulation layer.

According to a third aspect of the invention, a power converter, in particular an inverter or a DC voltage converter, having a power module according to the first aspect is described. The power converter according to this third aspect thus benefits from the above-mentioned advantages of the power module.

It should be noted that embodiments of the invention have been described with reference to different types of subject matter of the invention. In particular, some embodiments of the invention are described by way of method claims and other embodiments of the invention are described by way of device claims. The person skilled in the art will, however, immediately realize when reading this application that, unless explicitly stated otherwise, in addition to a combination of features belonging to one type of subject matter of the invention, any combination of features belonging to different types of subject matter of the invention is also possible.

### BRIEF DESCRIPTION OF THE DRAWINGS

Further advantages and features of aspects of the present invention are apparent from the following exemplary description of a preferred embodiment.

FIG. 1 shows a power module according to an exemplary embodiment.

FIG. 2 shows three heat- and current-conducting elements according to an exemplary embodiment.

FIG. 3 shows a switching bridge according to an exemplary embodiment.

FIG. 4 shows a flowchart of a method for producing a power module according to an exemplary embodiment.

It should be noted that the embodiments described below represent only a limited selection of possible implementation variants of the invention.

### DETAILED DESCRIPTION OF EXEMPLARY EMBODIMENTS

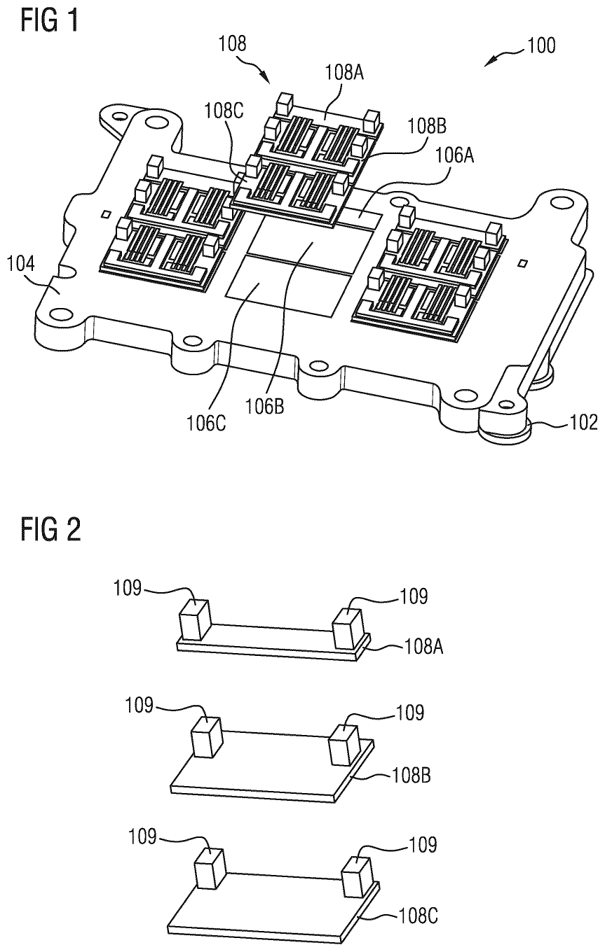

FIG. 1 shows a power module 100 according to an exemplary embodiment. The power module 100 has a cooler 102, an insulation layer 104 provided on a surface of the cooler 102, a conductor layer structure 106A, 106B, 106C provided on the insulation layer 104, and a plurality of heat- and current-conducting elements in the form of copper elements (i.e. of copper or a copper alloy) 108A, 108B, 108C. Each copper element 108A, 108B, 108C serves as a heat distributor and at the same time as a power conductor or power connection and has in each case an upper side and a lower side. The upper side is configured to form an electrical connection for an electronic component and the lower side is configured to make direct contact with the conductor layer structure. The insulation layer 104 preferably consists of an electrically insulating material, e.g. an organic or ceramic material. The conductor layer structure 106A, 106B, 106C is preferably formed of an electrically and thermally conductive material, in particular copper, and consists of a plurality of groups of three of rectangular areas 106A, 106B, 106C on the insulation layer 104. For each group of three of rectangular areas 106A, 106B, 106C, a group of three 108 of copper elements or heat distributors 108A, 108B, 108C is provided. It should be noted that the areas 106A, 106B, 106C may also have shapes other than rectangular, in particular may be triangular, elliptical or circular or consist of one or more polygons.

FIG. 2 shows three copper elements 108A, 108B, 108C of such a group of three 108 in more detail. More specifically, FIG. 2 shows a copper element 108A, which is set up as a heat distributor and as a negative connection for a switching bridge, a copper element 108B, which is set up as a heat distributor and as a phase current connection for a low-side semiconductor of a switching bridge, and a copper element 108C, which is set up as a heat distributor and as a positive connection for a high-side semiconductor of a switching bridge. The shape and size of the copper elements 108A, 108B, 108C in each case correspond to the shape and size of the rectangular areas 106A, 106B, 106C. Each copper element 108A, 108B, 108C has two block-shaped elements as spacers 109 which are set up for connecting to one or more busbars.

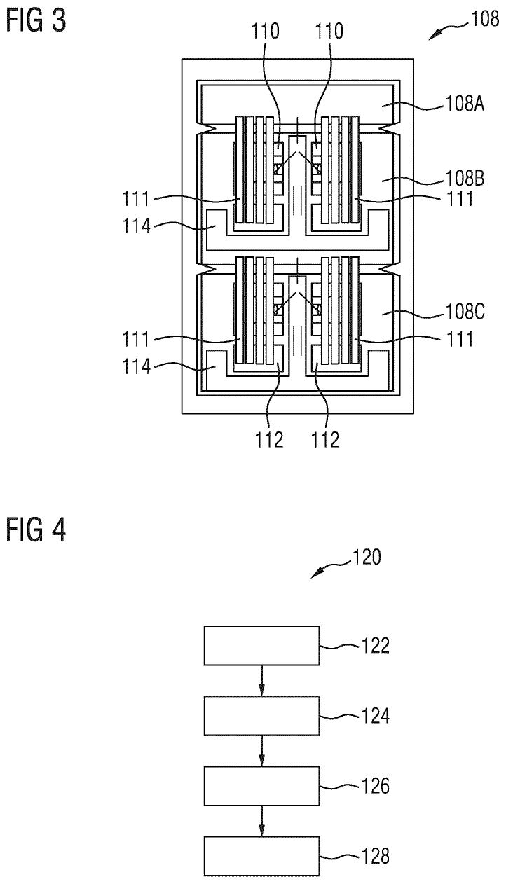

FIG. 3 shows a plan view of a switching bridge 108 according to an exemplary embodiment which is also shown in FIG. 1. The switching bridge has three copper elements 108A, 108B, 108C which have just been described in connection with FIG. 1 and FIG. 2. Attached to the copper elements 108B and 108C are semiconductor components 110, 112 which are at least partially surrounded by insulating material 114 and connected by means of bonding wires or bonding bands 111.

FIG. 4 shows a flowchart 120 of a method for producing a power module 100 according to an exemplary embodiment. The method begins at 122 with the provision of a cooler 102. At 124, an insulation layer 104 is formed on a surface of the cooler 102 and at 126, conductor layer structure 106A, 106B, 106C is formed on the insulation layer 104. At 128, a plurality of copper elements 108A, 108B, 108C are provided, each having an upper side and a lower side, wherein the upper side is configured to form an electrical connection for an electronic component 110, 112 and the lower side is configured to make direct contact with the conductor layer structure 106A, 106B, 106C.

In the embodiments described above, the function of the conductor layer structure as a heat conductor was particularly emphasized. However, it should be noted that the conductor layer structure 106A, 106B, 106C can also be used for the wiring level of signals, electrical components or other functions (e.g. placement of a temperature sensor). In other words, the conductor layer structure 106A, 106B, 106C can be used for both thermal and electrical conduction.

1. A power module having
a cooler,
an electrical insulation layer on a surface of the cooler,
an electrical conductor layer structure on a side of the insulation layer facing away from the cooler, and
a plurality of heat- and current-conducting elements made of a metal or a metal alloy or copper or a copper alloy, each having an upper side and a lower side,
wherein the respective lower side of the heat- and current-conducting elements is arranged on a side of the conductor layer structure facing away from the cooler and is electrically and thermally connected to the conductor layer structure,
semiconductor components which are each arranged on the upper side of the respective heat- and current-conducting elements and are electrically and thermally connected to the respective heat- and current-conducting elements.

2. The power module as claimed in claim 1, wherein the insulation layer is formed of an organic, electrically insulating material or of a ceramic, electrically insulating material.

3. The power module as claimed in claim 1, wherein the underside of the heat- and current-conducting elements is soldered or sintered or glued or welded onto the conductor layer structure.

4. The power module as claimed in claim 1, wherein the semiconductor components are each soldered or sintered or glued or welded onto the upper side of the respective heat- and current-conducting elements.

5. The power module as claimed in claim 1, wherein the conductor layer structure has a plurality of electrically conductive areas which are physically and electrically separated from each other.

6. The power module as claimed in claim 5, wherein arranged on each of the areas in each case is at least one heat- and current-conducting element which is electrically and thermally connected to the respective corresponding area.

7. The power module as claimed in claim 6, wherein the areas are arranged in groups of three, wherein the three areas of the respective group of three form a negative current connection, a phase current connection and a positive current connection, respectively, of the power module.

8. The power module as claimed in claim 1, wherein the heat- and current-conducting elements are plate or block-shaped.

9. The power module as claimed in claim 1, wherein the heat- and current-conducting elements are arranged in groups of three, wherein the three heat- and current-conducting elements of the respective group of three form a negative current connection, a phase current connection and a positive current connection, respectively, of the power module.

10. The power module as claimed in claim 1, which further has electrically conductive spacers which are each soldered or sintered or glued or welded onto the upper side of the respective heat- and current-conducting elements and are set up to make electrical connections between the heat- and current-conducting elements on the one side and external electrical contact partners of the power module on the other side and at the same time to establish spatial distance between the heat- and current-conducting elements on the one side and the external electrical contact partners on the other side.

11. The power module as claimed in claim 10, wherein the spacers are block-shaped or column-shaped.

12. A method for producing a power module as claimed in claim 1, the method comprising:
providing (122) a cooler,
forming an electrical insulation layer on a surface of the cooler,
forming (126) a conductor layer structure on a side of the insulation layer facing away from the cooler,
providing a plurality of heat- and current-conducting elements made of a metal or a metal alloy or copper or a copper alloy, each having an upper side and a lower side,
arranging the heat- and current-conducting elements on a side of the conductor layer structure facing away from the cooler, wherein the respective lower side of the heat- and current-conducting elements is placed onto the conductor layer structure and is electrically and thermally connected to the conductor layer structure,
arranging semiconductor components on the respective corresponding heat- and current-conducting elements and electrically and thermally connecting the semiconductor components to the respective corresponding heat- and current-conducting elements.

13. A power converter having a power module as claimed in claim 1.

14. The power module as claimed in claim 2, wherein the underside of the heat- and current-conducting elements is soldered or sintered or glued or welded onto the conductor layer structure.
